(19) United States
(12) Patent Application Publication
(10) Pub. No.: US 2015/0111483 A1
(43) Pub. Date: Apr. 23, 2015

(54) SERVER CABINET

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: LEI LIU, Shenzhen (CN); GUO-YI CHEN, Shenzhen (CN)

(73) Assignees: HON HAIPRECISION INDUSTRY CO., LTD., New Taipei (TW); HONG FU JIN PRECISION INDUSTRY (ShenZhen) CO., LTD., Shenzhen (CN)

(21) Appl. No.: 14/141,446

(22) Filed: Dec. 27, 2013

(30) Foreign Application Priority Data
Oct. 22, 2013 (CN) 2013104979488

(51) Int. Cl. H05K 7/20

(52) U.S. Cl. CPC H05K 7/20718; H05K 7/20136
USPC 454/184

(57) ABSTRACT

A server cabinet includes a cabinet, a fan module, and two fixing members. The cabinet includes a rear panel defining an opening. The fan module includes a bracket. The bracket includes a first receiving portion and a second receiving portion substantially perpendicular to the first receiving portion. The first receiving portion and the second receiving portion each receive a fan. The fan module is pivotably received in the opening. When the first receiving portion is exposed out of the opening, the fan in the first receiving portion dissipates heat from the cabinet. The fixing members prevent the fan module from rotating. When the second receiving portion is exposed out of the opening, the fan in the second receiving portion dissipates heat from the cabinet, and the fixing members prevent the fan module from rotating.

### BACKGROUND

1. Technical Field

The present disclosure relates to a server cabinet.

2. Description of Related Art

Server cabinets are generally equipped with fan modules for dissipating heat generated by servers in the server cabinets. Each fan module comprises at least two fans. However, if one of the fans breaks, and there is no spare fan to replace the broken fan, heat from the server cabinets may not be dissipated effectively. Therefore, there is room for improvement in the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a server cabinet, wherein the server cabinet comprises a fan module.

FIG. 2 is an assembled, isometric view of FIG. 1.

FIG. 3 is similar to FIG. 2, but showing the fan module in another state.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references can mean “at least one.”

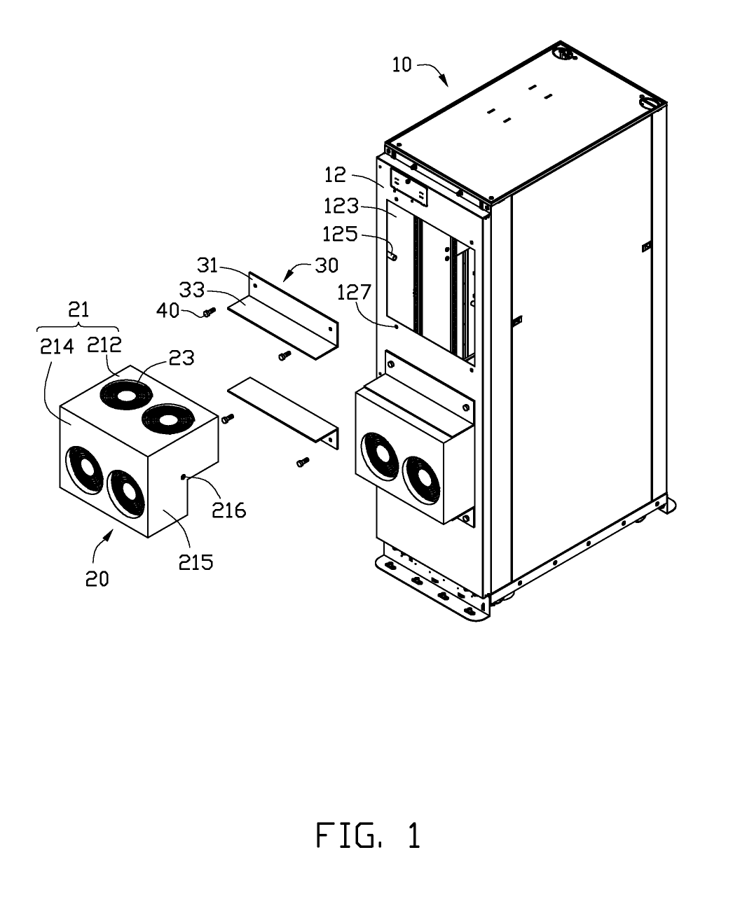

FIG. 1 shows an exemplary embodiment of a server cabinet comprising a cabinet 10, two fan modules 20, and four fixing members 30. In other embodiments, the server cabinet can comprise different numbers of the fan modules 20 and of the fixing members 30 according to actual needs.

The cabinet 10 comprises a rear panel 12 defining two openings 123. Two pivots 125 extend toward each other from an inner side of the rear panel 12 bounding opposite ends of each opening 123. Two fixing holes 127 are defined in the rear panel 12 below each opening 123, and another two fixing holes 127 are defined in the rear panel 12 above each opening 123.

Each fan module 20 comprises a bracket 21. The bracket 21 comprises a first receiving portion 214 and a second receiving portion 212 connected substantially perpendicularly to a side of the first receiving portion 214. Two fans 23 are received in each of the first receiving portion 214 and the second receiving portion 212. The bracket 21 comprises two substantially L-shaped opposite sidewalls 215. A pivot hole 216 is defined adjacent to an inner corner of each sidewall 215.

Each fixing member 30 comprises a fixing plate 31 and a stopping plate 33 connected substantially perpendicularly to a side of the fixing plate 31.

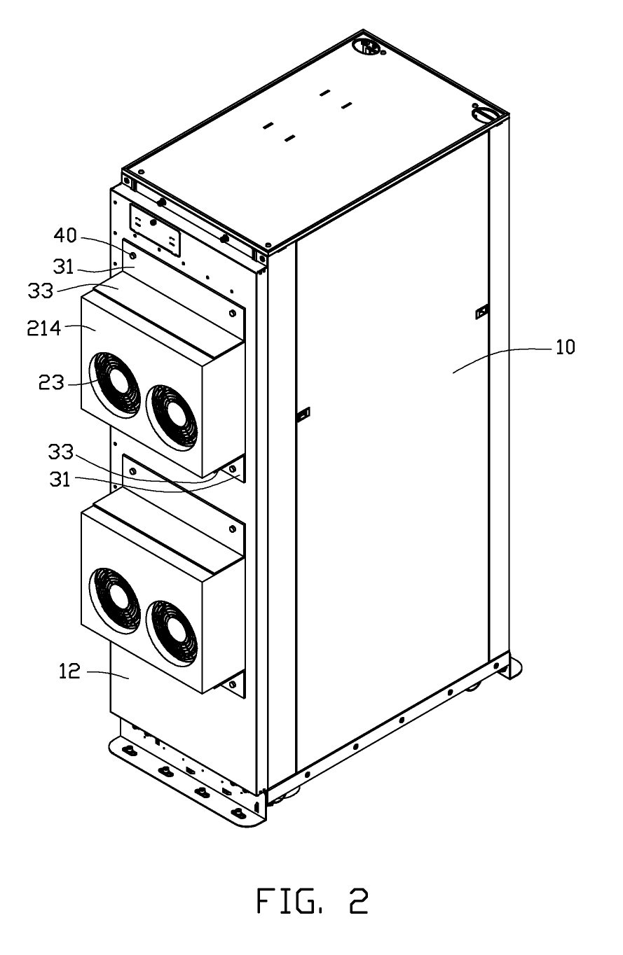

FIG. 2 shows that in assembly of each fan module 20, the two opposite pivots 125 are received in the corresponding pivot holes 216 of the fan module 20. Thus, the fan module 20 is pivotably received in the corresponding opening 123, such that the first receiving portion 214 is vertically exposed out of the opening 123. The fans 23 in the first receiving portion 214 are electrically connected to a power supply (not shown). Fasteners 40, such as screws, are received through the corresponding fixing plates 31 of the fixing members 30, and the corresponding fixing holes 127, such that the stopping plates 33 abut sides of the corresponding fan modules 20. Thus, the fixing members 30 are fixed to the rear panel 12 respectively above and below the corresponding opening 123 and sandwich the corresponding fan module 20. The fan modules 20 are prevented from rotating by the corresponding two stopping plates 33.

In use, the fans 23 of the first receiving portions 214 operate to dissipate heat from the cabinet 10.

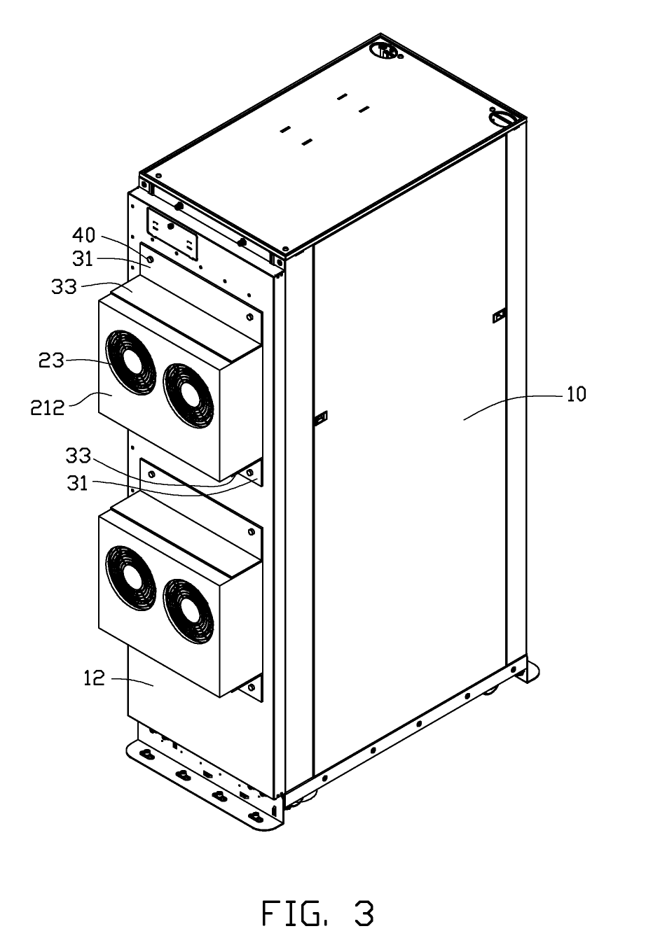

Referring to FIG. 3, if one or two fans 23 of one of the first receiving portions 214 is broken, the corresponding fixing members 30 are detached from the rear panel 12, and the fans 23 in the first receiving portion 214 are disconnected from the power supply. The fan module 20 is rotated to allow the second receiving portion 212 to be vertically exposed out of the corresponding opening 123, and the fans 23 in the second receiving portion 212 are electrically connected to the power supply. Then, the fixing members 30 are again fixed to the rear panel 12 by the fasteners 40 and sandwich the corresponding fan module 20. Thus, the fans 23 in the second receiving portion 212 operate to dissipate heat from the cabinet 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A server cabinet, comprising:
a cabinet comprising a rear panel defining an opening;
a fan module comprising a bracket, the bracket comprising a first receiving portion and a second receiving portion substantially perpendicular to the first receiving portion, wherein the first receiving portion and the second receiving portion each receive at least one fan; and
two fixing members, wherein the fan module is pivotably received in the opening of the cabinet, when the first receiving portion is rotated to be exposed out of the opening, the at least one fan in the first receiving portion dissipates heat from the cabinet, the fixing members are located to the rear panel respectively above and below the opening and sandwich the fan module; when the second receiving portion is rotated to be exposed out of the opening, the at least one fan in the second receiving portion dissipates heat from the cabinet, and the fixing members are located to the rear panel respectively above and below the opening and sandwich the fan module.

2. The server cabinet of claim 1, wherein the second receiving portion is connected perpendicularly to a side of the first receiving portion.

3. The server cabinet of claim 2, wherein the bracket of the fan module comprises two substantially L-shaped opposite sidewalls, a pivot hole is defined adjacent to an inner corner of each sidewall, and two pivots protrude from an inner side of the rear panel bounding opposite ends of the opening, to pivotably engage in the pivot holes of the fan module.

4. The server cabinet of claim 3, wherein when the first receiving portion is exposed out of the opening, the first receiving portion is in a vertical position; when the second receiving portion is exposed out of the opening, the second receiving portion is in a vertical position.

5. The server cabinet of claim 1, wherein the rear panel defines two fixing holes below the opening, and another two fixing holes above the opening, four fasteners are received through the fixing members and corresponding fixing holes, to detachably connect the fixing members to the rear panel.

6. The server cabinet of claim 1, wherein each fixing member comprises a fixing plate detachably mounted to the rear panel, and a stopping plate connected substantially perpendicularly to a side of the fixing plate, when the fixing members are located to the rear panel respectively above and below the opening, the fan module is sandwiched between the stopping plates.
